(19) United States
(12) Patent Application Publication
(10) Pub. No.: US 2014/0042564 A1
(43) Pub. Date: Feb. 13, 2014

(54) INTEGRATED-CIRCUIT SWITCH

(71) Applicants: Chou-Hsien Tsai, New Taipei City (TW); Chia-Chin Su, New Taipei City (TW)

(72) Inventors: Chou-Hsien Tsai, New Taipei City (TW); Chia-Chin Su, New Taipei City (TW)

(21) Appl. No.: 14/113,942

(22) PCT Filed: Apr. 12, 2012
(86) PCT No.: PCT/CN2012/073943

§ 371 Date: Oct. 25, 2013

(30) Foreign Application Priority Data
Apr. 25, 2011 (CN) 20110103821.4

(51) Int. Cl. H01L 29/84; H01L 23/00

(52) U.S. Cl. CPC H01L 29/84; H01L 24/83
USPC 257/415; 438/51

(57) ABSTRACT

A switch and the manufacturing method thereof are provided. The switch comprises a chip structure providing a one-piece bonding surface. An actuating member of a mechanical switch could receive an external force to contact the one-piece bonding surface so as to actuate the chip structure.

### FIELD OF THE INVENTION

The present invention relates to a switch, and more particularly to an integrated-circuit switch.

### BACKGROUND OF THE INVENTION

Switch is one of the most important elements in an electrical/mechanical device, which is normally applied to a small volume electrical/mechanical switch in an application system, with low voltage or low current generally. On the other hand, when the application system needs to be applied with high voltage or high current, the mechanical switch will be replaced by an electrical switch which is combined with a circuit and a mechanical switch.

However, while a user applied the electrical switch in the application system with high voltage or high current, here comes the drawback that the cost is high, or the circuit is customized with complicated design or hard to be carried out. Moreover, a problem is generated that the volume of the electrical switch circuit is too big. Therefore, how to combine the mechanical structure and the electrical structure effectively to put it into practice easily and how to be applied in an electromechanical integrated switch with high voltage or high current, is what we should improve now.

### SUMMARY OF THE INVENTION

The present invention provides a switch and a manufacturing method forming the same. Rely on combining the mechanical switch and the grain, when the mechanical switch contacts a one-piece bonding surface, the grain is actuated.

The present invention provides an integrated-circuit switch. Wherein, the packaging member is formed with a one-piece bonding surface for the actuating structure of the mechanical switch, and then the actuating structure is assembled to the integrated-circuit switch.

The present invention provides an integrated-circuit switch. Wherein, the packaging member itself is a heat dissipating member, so as to increase the heat dissipating area and meet the goal of heat dissipation.

In accordance with an aspect of the present invention, there is provided an integrated-circuit switch. The integrated-circuit switch comprises a chip structure having a one-piece bonding surface in contact with an actuating member, wherein the chip structure comprises a protective fixture; a grain disposed in the protective fixture, and a coupling member disposed in the protective fixture and coupled with the grain. Wherein the grain is actuated as a result of contact with the actuating member, and the one-piece bonding surface is at least provided by the coupling member.

In accordance with an aspect of the present invention, there is provided a switch. The switch comprises a chip structure and an actuating member combining thereof, wherein the chip structure has a one-piece structure for combing the actuating member, and the actuating member has an operating area exposed outside the integrated-circuit switch for receiving an external force.

In accordance with an aspect of the present invention, there is provided manufacturing method for a switch. The manufacturing method for a switch comprises the following steps of: forming a chip structure having a one-piece bonding surface; and assembling an actuating member and the chip structure, wherein the actuating member is assembled to the one-piece bonding surface, and the actuating member has an operating area exposed outside the switch for receiving an external force.

In accordance with an aspect of the present invention, there is provided a switch. The switch comprises a chip structure and an actuating member. Whereon the chip structure comprises a protective fixture, a grain disposed in the protective fixture, and a coupling member disposed in the protective structure and electrically connected with the grain. The actuating member limited by the protective fixture and actuating the chip structure, wherein the actuating member is subjected to an external force to so as to contact both of the grain and the coupling member or contact either of the grain and the coupling member.

In an embodiment, the coupling member comprises a wire frame with a plurality of signal pins, and the signal pins are electrically connected with a plurality of conductive pads of the grain correspondingly. And, the coupling member further comprises a plurality of conductive structures for connecting the signal pins and the conductive pads. Or, the protective fixture comprises a plurality of attachment structure for fixing the signal pins onto an active face of the grain, and the conductive pads are disposed on the active face. Or, when the actuating member contacts the chip structure, at least a part of any of the signal pins moves a distance to be electrically connected to and in contact with the conductive pads correspondingly. And, the signal pin moving the distance provides the one-piece bonding surface.

In an embodiment, the protective fixture comprises a plurality of sealing structures covering parts of the signal pins and the conductive pads. And, the sealing structures further cover a plurality of conductive structures connecting the signal pins and the conductive pads.

In an embodiment, at least a pair of the signal pins is disposed on the grain correspondingly, and the pair of signal pins provides the one-piece bonding surface. And, the pair of signal pins further comprises a plurality of limiting parts, and the one-piece bonding surface further involves the limiting parts.

In an embodiment, the coupling member further comprises a grain holder disposed on a back side of the grain, and the conductive pads are disposed on an active face opposite to the back side. And, the grain holder is exposed outside the protective fixture so as to provide the one-piece bonding surface. Or, the grain holder comprises a plurality of separated parts, and the separated parts jointly form a groove away from the back side and provide the one-piece bonding surface. Or, the coupling member further comprises a plurality of conductive structures connecting parts of the signal pins to the grain holder. Or, the protective fixture comprises a sealing body sealing the grain and covering parts of the grain holder and the signal pins. Or, the one-piece bonding surface is additionally provided by the sealing body, the one-piece bonding surface involves the uncovered grain holder and the sealing body disposed around the grain holder. Or, the one-piece bonding surface is additionally provided by the sealing body, the one-piece bonding surface involves the uncovered grain holder, the sealant disposed around the grain holder and the uncovered signal pins. Or, parts of the signal pins are exposed outside the sealing body, the exposed parts of the signal pins is adjacent to an active face of the grain opposite to the sealing body, or adjacent to a surface of the sealing body exposed via the grain holder, or exposed on a lateral wall of the grain structure. Or, the one-piece bonding surface is additionally provided by the exposed parts of the signal pins. Or, the exposed grain holder further comprises an extending portion extending from the grain holder to a surface of the sealing body opposite to the active face of the grain, wherein the extending portion or the exposed grain holder is a part of the one-piece bonding surface.

In an embodiment, some of the signal pins comprise an extending portion contacting a thermal conductive back side of the grain, and the conductive pads are disposed on an active surface opposite to the thermal conductive back side. And, the one-piece bonding surface is provided by the extending portion.

In an embodiment, the chip structure comprises a packaging member, the packaging member comprises Single inline Package (SIP), dual-inline package, metal can package or flat package, wherein the flat package comprises Quad Flat Package (QFP), Quad Flat package No-lead (QFN), quad package with bump, quad package with guard ring, Pin Grid Array Package (PGA), Ball Grid Array Package (BGA), Chip Size Package (CSP), Chip On Board (COB), flip-chip, Leadless Chip Carrier, LCC or Quad flat non-leaded Package (QFN), Land Grid Array (LGA), Lead On Chip (LOC), Multi-Chip Module (MCM) or Over Molded Pad Array Carrier.

In an embodiment, the packaging member is formed with the protective fixture and the coupling member.

In an embodiment, the actuating member is in contact with the one-piece bonding surface and an external element in order, by turns or simultaneously. And, the actuating member contacts the chip structure responding to an external force applied thereon.

In an embodiment, the actuating member has an operating area exposed outside the integrated-circuit switch for receiving the external force. And, the operating area is a force-exerting area of the integrated-circuit switch.

The mechanical switch and the grain could be combined together efficiently of this invention. Wherein, when the mechanical switch contacts a one-piece bonding surface, the grain is actuated. With such an arrangement, the electromechanical integrated switch is applied easily and suit for high voltage and high current. Moreover, the one-piece bonding surface, for bonding the actuating structure of the mechanical switch thereon, is formed on the packaging structure, so that the actuating structure and the integrated-circuit are assembled with each other. Thus, the packaging member itself is served as a heat dissipating member to increase the heat dissipating area and meet the goal of heat dissipation.

### BRIEF DESCRIPTION OF THE DRAWINGS

FIG. 1 is a block diagrams illustrating an integrated-circuit switch and an actuating member of the present invention.

FIG. 2 is a block diagrams illustrating an integrated-circuit switch and an actuating member of the present invention.

FIG. 3 is a schematic perspective view illustrating the first embodiment of the grain and the wire frame of the present invention.

FIG. 4 is a schematic sectional exploded view illustrating the grain, the limiting pin, the protective fixture and the actuating structure shown in FIG. 3 of the present invention.

FIG. 5 is a schematic sectional view illustrating the grain, the actuating signal pin and the protective fixture shown in FIG. 3 of the present invention.

FIG. 6 is a schematic sectional view illustrating the grain, the general signal pin and the protective fixture shown in FIG. 3 of the present invention.

FIG. 7 is a schematic sectional exploded view illustrating the second embodiment of the grain, the actuating signal pin, the protective fixture and the actuating structure of the present invention.

FIG. 8 is a schematic perspective view illustrating the third embodiment of the grain and the wire frame of the present invention.

FIG. 9 is a schematic side view illustrating the fourth embodiment of the chip structure comprising the Quad Flat package No-lead of the present invention.

FIG. 10 is a schematic side view illustrating the chip structure combined with the actuating member shown in FIG. 3 of the present invention.

FIG. 11 is a schematic side view illustrating the fifth embodiment of the chip structure comprising the similar Quad Flat Package of the present invention.

FIG. 12 is a schematic side view illustrating the sixth embodiment of the chip structure comprising the Quad Flat Package of the present invention.

FIG. 13 is a schematic side view illustrating the seventh embodiment of the chip structure comprising the Quad Flat Package No-lead of the present invention.

FIG. 14 is a schematic side view illustrating the eighth embodiment of the chip structure comprising the Quad Flat Package No-lead of the present invention.

FIG. 15 is a schematic perspective view illustrating the ninth embodiment of the chip structure comprising the Quad Flat Package No-lead of the present invention.

FIG. 16 is another schematic perspective view illustrating the ninth embodiment of the chip structure comprising the Quad Flat Package No-lead of the present invention.

FIG. 17 is a schematic perspective view illustrating the tenth embodiment of the chip structure comprising the Quad Flat Package No-lead of the present invention.

FIG. 18 is another schematic perspective view illustrating the tenth embodiment of the chip structure comprising the Quad Flat Package No-lead of the present invention.

FIG. 19 is a flow chart illustrating the manufacturing method for the switch of the present invention.

### DETAILED DESCRIPTION OF THE PREFERRED EMBODIMENT

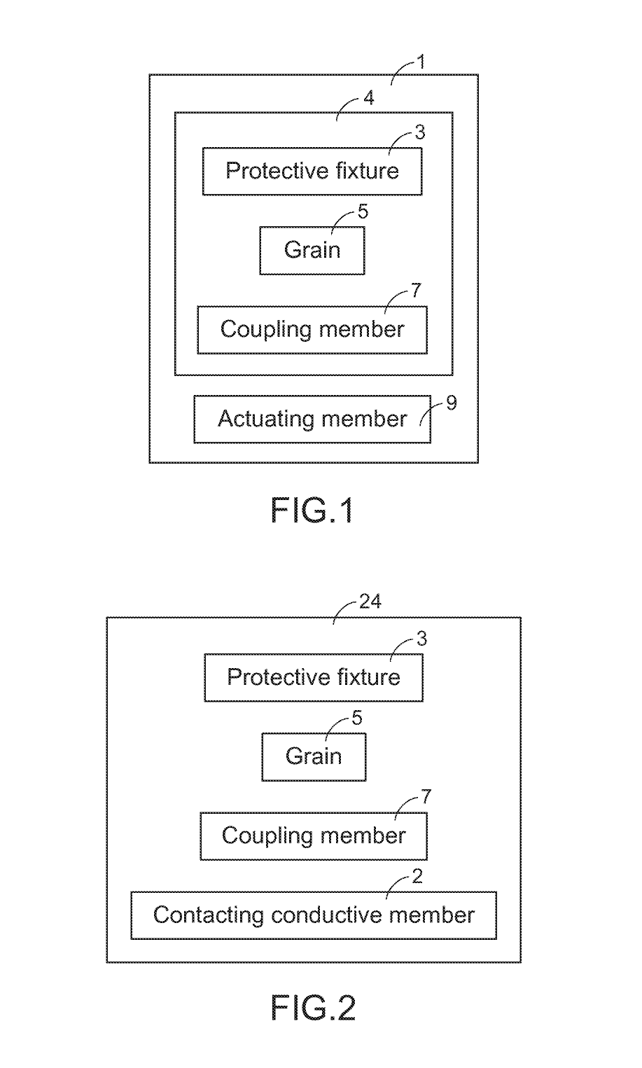

FIG. 1 and FIG. 2 are two block diagrams illustrating an integrated-circuit switch and an actuating member. Referring to FIG. 1, the integrated-circuit switch 1 comprises a chip structure comprising a protective fixture 3, a grain 5 and a coupling member 7. The chip structure 4 provides a one-piece bonding surface to be in contact with an actuating member 9, and the one-piece bonding surface could be provided by the coupling member 7 alone or provided by the coupling member 7 and the protective fixture 3 jointly. The protective fixture 3 and the coupling member 7 are assembled together to serve as a packaging member, wherein the protective fixture 3 is used for fixing and/or protecting grain 5 and the coupling member 7. The actuating member 9 is used for receiving a force, when the force is applied on the actuating member 9, the actuating member 9 contacts the coupling member 7 and actuates the grain 5. With such an arrangement, the coupling member 7 provides a first function path for grain 5. In this invention, the grain 5 is integrated into the mechanical switch so as to be actuated by the mechanical switch and then processing signals thereafter. Furthermore, signals outputted from the grain 5 are guided or transmitted via the first function path provided by the coupling member 7.

Referring to FIG. 2, in addition to the protective fixture 3, the grain 5 and the coupling member 7, the chip structure 4 further comprises a contacting conductive member 2 used to form a second function path. It should be noted herein that electrical signals, photo signals, magnetic signals or heat signals could be guided and transmitted via the function path. In other words, a physical signal generated by the grain 5 could be guided to the surroundings from an interior or a surface of the grain 5 via the second function path. Therefore, the contacting conductive member 2 could also provide a one-piece bonding surface.

It is understandable that when the grain 5 is processing the signals, there must be a little heat generated by the grain 5 in the meantime. However, when the heat can not be dissipated from the grain 5 to the surroundings rapidly, the heat will be accumulated in the grain 5 and make the temperature of the grain 5 get higher. Under this circumstance, the process efficiency of the grain 5 is low, or the output efficiency of the grain 5 is not regular.

As mentioned above, when a mechanical switch integrated with the grain, the problem should be solved is that the heat in the interior or on the surface of the grain how to be dissipated away from the grain to the surroundings rapidly or effectively. It should be noted herein that the grain is a wafer made of Si, and manufactured by pattern transferring, developing, etching, thin film deposition and ion implantation. After that, circuits or elements are arranged on the wafer, and the wafer is divided into several segments and forming the grains Therefore, if the material and the component of the grain itself are of high electrical coefficient and high thermal conductivity, the grain itself may be served as a first function path to transfer the heat, generated during the grain processing, to a surface of the grain. If a high conductive component is arranged on the surface of the grain, such as the contacting conductive member 2 of this invention, which could be served as a second function path. Then, the second function path is an additional path for transferring or dissipating the heat generated by grain 5, and the heat will be dissipated away from the grain 5 to the surroundings rapidly or effectively.

Conventionally, the coupling member provides the first function path, and people usually use a sealant or a shell to fix and protect the coupling member. The material of the sealant or the shell is of high thermal conductivity, so as to dissipate the heat from the surface of the grain rapidly. Therefore, the conventional packaged grain (or so-called packaged chip), could comprise a heat dissipating design inside the packaged body. The protective fixture of this invention is not only used for fixing and protective the grain, but also used for fixing and protecting the other components which are interactive with the grain individually or jointly with coupling member.

Therefore, the protective fixture of the present invention is arranged with the coupling member together, to be served as a packaging member. The packaging member comprises but is not limited to Single inline Package (SIP), dual-inline package, metal can package or flat package. Wherein the flat package comprises but is not limited to Quad Flat Package (QFP), Quad Flat package No-lead (QFN), quad package with bump, quad package with guard ring, Pin Grid Array Package (PGA), Ball Grid Array Package (BGA), Chip Size Package (CSP), Chip On Board (COB), flip-chip, Leadless Chip Carrier, LCC or Quad flat non-leaded Package (QFN), Land Grid Array (LGA), Lead On Chip (LOC), Multi-Chip Module (MCM) or Over Molded Pad Array Carrier.

In more detail, the contacting conductive member 2 could be the coupling member 7, protective fixture structure 3 or the actuating member 9, or could be the combination of at least two of the following elements: the coupling member 7, the protective fixture structure 3 and the actuating member 9. With such an arrangement, the integrated-circuit switch would provide another function path for enhancing the efficiency of the heat dissipation.

In more detail, the coupling member 7 could provide the contacting conductive member 2 in this invention. On the basis above, when the first function path provided by the coupling member 7 guides or transmits the output signal from the grain 5, the heat generated by the grain could also dissipate from the grain 5 to the surroundings via the first function path in the meantime. Wherein, the coupling member 7 is designed for guiding and transmitting the output signal from the grain. However, the coupling member 7 of this invention is capable of looking after the both sides of guiding and transmitting the output signal of the grain and increasing a dissipating area on a surface of the grain 5 of the integrated-circuit switch.

Furthermore, the grain 5 could provide the contacting conductive member 2 in the present invention. On the basis above, while the grain 5 is processing, the grain 5 itself would be a heat source, and the contacting conductive member 2 is close to the heat source to guide and transfer the heat outward in a shortest distance to achieve the goal of rapid heat dissipation. Therefore, in addition to the coupling member 7 which is used for coupling, the grain 5 of this invention provides a contacting conductive member 2 dissipating directly, the contacting conductive member 2 is close to the surroundings and contacts a conductive member in the surroundings directly, so as to dissipate the heat from the grain 5.

The grain 5 is disposed in the protective fixture 3, therefore, the protective fixture 3 could provide as a heat dissipating member to guide and transfer the heat outside in a short distance.

Further, the switch of this invention could be a knife switch with single pole, two-pole, and three-pole suit for a firesafety device, or a change-over switch (or so-called combination switch), a push button switch suit for a controlling electrical device or a position switch (or so-called position limit switch or lead position limit switch). The actuating members would be a little different corresponding to each of the above mentioned switches. For example, the actuating structure of the position switch could have different contact system as the actuating member. Such as slide system, rotary system, rolling system, slightly movable system. Further, the actuating structure of the push button switch could comprise several actuating members of the movable contact and the fixed contact, such as a dome/a metal dome or an elastic strip, but is not limited herein. Selectively, the configuration of this invention could be a thin film switch, and the actuating member could be a conductive film or a flexible print circuit board.

It should be noted herein that the switch of this invention could be jointly utilized by the chip structure and the other elements thereof. Therefore, the chip structure could be a part of element which could be actuated of the switch. The actuating member could actuate the chip structure and external element in order, by turns or simultaneously, thereby, a user could apply a force to the same switch to actuate different elements in order, by turns or simultaneously. As mentioned above, if the chip structure provides a bonding surface for being combined with the actuating member of the switch, the actuating member of the switch will actuate the chip structure but not influence the operation of the switch and not actuate other elements in the switch or other elements connecting to the switch.

On the basis of the above, there are several different instances to describe the integrated-circuit switch as follows.

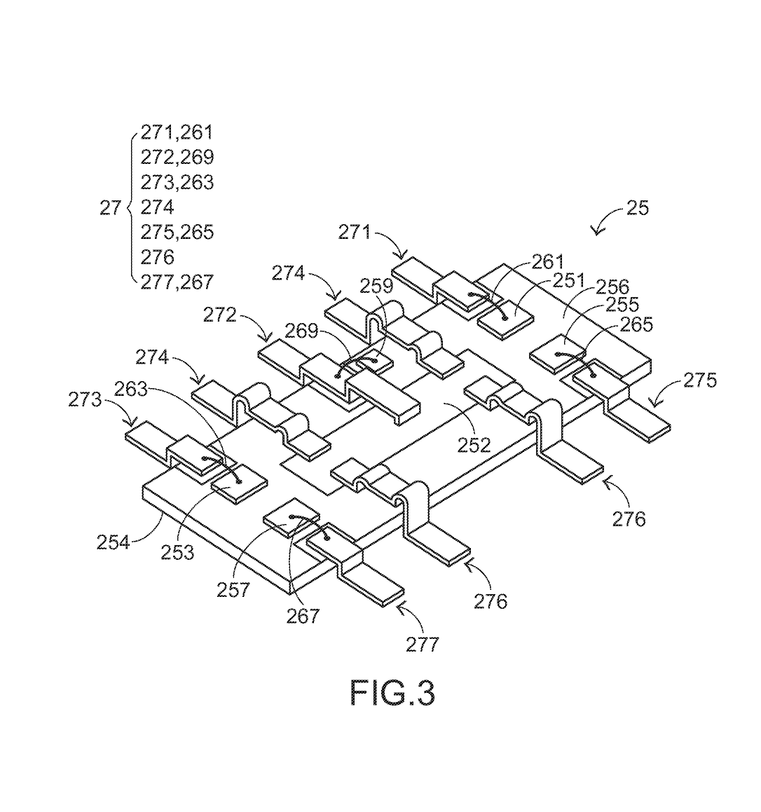

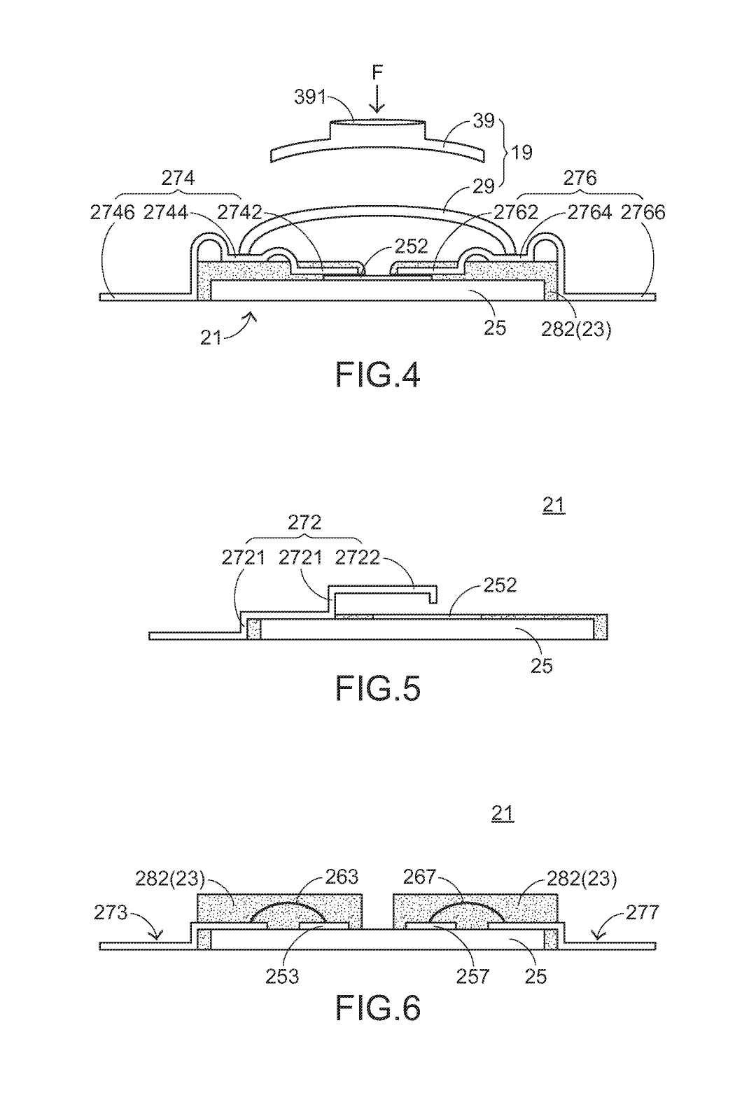

FIG. 3 illustrates a schematic perspective view of the first embodiment of the grain and the wire frame of the present invention, FIG. 4 illustrates a schematic sectional view of the grain, the limiting pin, the protective fixture and the actuating structure of the present invention, FIG. 5 illustrates a schematic perspective view of the grain, the actuating signal pin and the protective fixture shown in FIG. 3, and FIG. 6. illustrate a schematic sectional view of the grain, the general signal pin and the protective fixture shown in FIG. 3. Referring to FIG. 3 and FIG. 4, the integrated-circuit switch 21 comprises grain 25, protective fixture 23 and coupling member 27. In the first embodiment, the integrated-circuit switch 21 is similar to the design of Lead On Chip.

In more detail, the grain 25 has an electrical insulating first surface 254 (back side) opposite to a second surface (active surface), and the grain 25 has a plurality of pads 251, 252, 253, 255, 257, 259 disposed on the second surface 256 for used to input or output physical signal. In the first embodiment, the conductive pad 252 is disposed on a center region of the second surface 256, pads 251, 253, 255, 257, 259 are arranged around the pad 252 on the second surface with intervals. The size of the pad 252 is larger than pads 251, 253, 255, 257, 259. Further, the pad 252 is used to ground, and the pads 251, 253, 255, 257, 259 is used to input or output electrical signal, for example: used to control signals, Vin, Vout etc, but is not limited herein. It is understandable that the amount and the size of the pads 251, 252, 253, 255, 257, 259 could be changed according to the function or the design of the grain 25, and it is not limited by FIG. 3.

Referring to FIG. 3, the wire frame is used to accomplish the coupling member 27 and the contacting conductive member. The material of the wire frame is comprising but not limited to non-nickel alloy, copper alloy (coalesced copper. deoxidized copper), or composite metal. On other aspects, the manufacturing method of the wire frame could comprise but not limit to stamp, etching, rolling or treating solution. Further, the shape could comprise but not limit to a thin plate or a needle.

In the first embodiment, the coupling member 27 comprises a plurality of signal pins 271, 273, 275, 277 of the wire frame, and comprises a plurality of conductive structures 261, 263, 265, 267, 269. The conductive structures 261, 263, 265, 267, such as conducting wires, are in contact with and electrically connected to the signal pin 271, 273, 275, 277 and the pad 251, 253, 255, 257. In more detail, the conductive structure 261 is in contact with and electrically connected to the signal pin 271 and pad 251, the conductive structure 263 is in contact with and electrically connected to the signal pin 273 and pad 253, the conductive structure 265 is in contact with and electrically connected to the signal pin 275 and pad 255, and the conductive structure 267 is in contact with and electrically connected to the signal pin 277 and pad 257.

Furthermore, the coupling member 27 further comprises an actuating signal pin 272. Similar to the signal pin 271, 273, 275, 277, the actuating signal pin 272 is in contact with and electrically connected to the pad 259 by the conductive structure 269. The actuating signal pin 272 comprises an inner part 2722, wherein, owing to a stage difference is formed with the actuating signal member 272 so that the inner part 2722 gets higher and an interval is existing between the inner part 2722 and the pad 252. In a normal condition, the actuating signal pin 272 does not contact the pad 252. In an actuating condition, while the actuating member 29 is receiving a force, the actuating member 29 makes the inner part 2722 of the actuating signal pin 272 move a distance to contact and electrically connects to the pad 252.

Referring to FIG. 4, the coupling member 27 further comprises a plurality of limiting pins 274, 276 of the wire frame. The limiting pins 274, 276 comprise an inner part 2742, 2762 in contact with pads 252 respectively. The limiting pins 274, 276 further comprise a limiting portion 2744, 2764 and pin-end portion 2746, 2766 respectively. In the first embodiment, the actuating 29 is loaded by the limiting portions 2744, 2764, and is movable within the limiting portions 2744, 2746. In order to make sure the actuating member 29 is moving on the limiting portions 2744, 2764, the limiting portions 2744, 2764 comprises one side or two sides weirs for the actuating member 29 leaning against thereon. However, the limiting portions 2744, 2764 will not be limited in the above design, the limiting portions 2744, 2764 could be formed by another way like stage difference in the present invention. Furthermore, the inner part, the limiting portion and the pin-end portion of each the limiting pin could exist one or more stage difference or no stage difference, so as to adjust the height of the grain in the integrated-circuit switch. Therefore, the limiting pin 274, 276 provides a one-piece bonding surface to load and combine with the actuating member 29. Referring to FIG. 4 and FIG. 5, the actuating structure 19 comprises an operating member 39 and the actuating member 29, and the actuating structure 19 could be integrated into the integrated-circuit switch to be a switch that a user can operate it directly. In the first invention, the operating member 39 provides an operating area 391 to be applied an external force F thereon. The external force F could be uniformly distribute and spread on the actuating member 29, then the actuating member 29 actuates the actuating pin 272 to make the actuating signal pin 272 to contact the pads 252.

Protective fixture 23 could comprise a structure for packaging conductive structures 261, 263, 265, 267, such as a sealing structure 281 (as shown in FIG. 6) packaging conductive structure 261, 263, 265, 267. The protective fixture 23 further comprises a plastic 282 structure formed around the grain 25 in an adequate method. Selectively, the protective fixture 23 could only comprises a plastic 282 structure made of packaging material, which covering parts of the signal pin, conductive structure, conductive pad and grain.

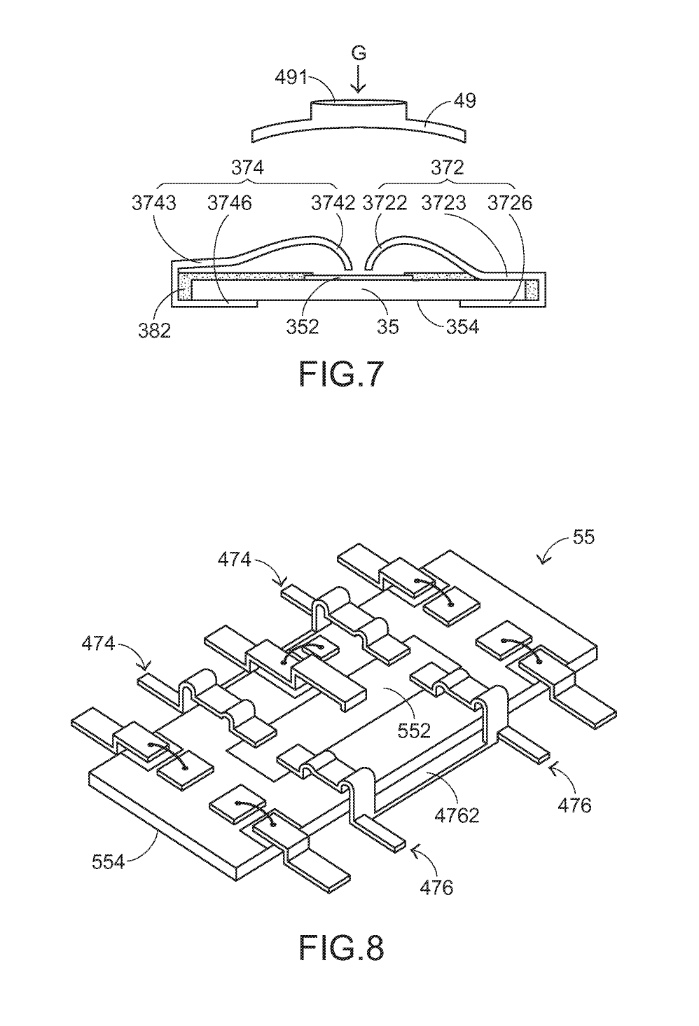

Selectively, the actuating signal pin of the wire frame could be integrated with the actuating member. The second embodiment of this invention is shown in FIG. 7, which shows the sectional view of the grain, the actuating signal member, and the protective fixture. Compare to the first embodiment, the actuating signal pins 372, 374 are served as the actuating member and respectively arranged on the two sides of the pad 352 of the grain 35 in symmetry in the second embodiment. The inner part 3722 is disposed above the pad 352 of the grain and keeping a distance from the pad 352. Parts of the extending portion 3723 is in contact with the grain 35, and the pin-end portion 3726 is in contact with first surface 354 of the grain 35. The inner part 3742 of the actuating signal pin 374 is disposed above the pad 352 of the grain 35, and keeping a distance from the pad 352. The extension part 3743 is not in contact with the grain 35, and the pin-end portion 3746 could be in contact with the first surface 354 of the grain 35. In addition, as the first embodiment, the two pin-end portions could be extending away from the grain 35. Furthermore, the extending portion 3723 connects the inner part 3722 and the pin-end portion 3726, and the plastic 382 fixes or covers the extending portion 3723 of the lateral wall of the grain 35.

As aforementioned, the suspending inner portions 3722, 3742 of the actuating signal pins 372, 374 provided a one-piece bonding curve surface. When a user applies an internal force G on the operating area 491 of the operating member 49, the external G transfers to each of the inner portions 3722, 3742 of the actuating signal pin 372, 374 respectively, so as to make the suspending inner portion 3722, 3742 contact the pad 352 of the grain 35. Furthermore, an actuating signal is generated to actuate the grain 35 to carry out the signal input, process, and output. It is understandable that parts of the pin of the wire frame receives the external force and moves a distance then contacts the grain, therefore, if a surface of the structure could be arranged above the pending inner portions 3722, 3742 of the actuating signal pin 372, 374, the limited actuating member in the first embodiment could be taken out. Wherein, the surface of the structure is not combined or limited by the coupling member.

However, the limiting parts of the limiting pin can either be taken out or retained in the second embodiment. With such an arrangement, the retained limiting parts could be served as a contacting conductive member to increase the conductive area and form a second function path. Then, the objective of rapid dissipation can be achieved.

Therefore, under the circumstance that the coupling member provides the first function path, the limiting pin is served as a contacting conductive member. As shown in FIG. 8, the third embodiment of the present invention, FIG. 8 illustrates a schematic perspective view of the grain and the wire frame. Compare to the first embodiment, the limiting pins 474, 476 comprise an extending portion of the first surface 554 in contact with the grain 55, in the meanwhile, the extending portion 4762 is served as the contacting conductive member of this invention and forming the dissipating area for dissipating the heat from the grain. In addition to provide the first function path, the coupling member further provides the second function path to guide the heat signal of the grain 55 outward. Because the extending portion 4762 is extending form parts of the limiting pins 474, 476 and the limiting pins 474, 476 is in contact with and electrically connected to the pad 552, the extending portion 4762 could be served as a one-piece bonding surface, to make the actuating member contact the pad 522. On the above basis, when the contacting conductive member is provided by the coupling member, the contacting conductive member is a one-piece bonding surface.

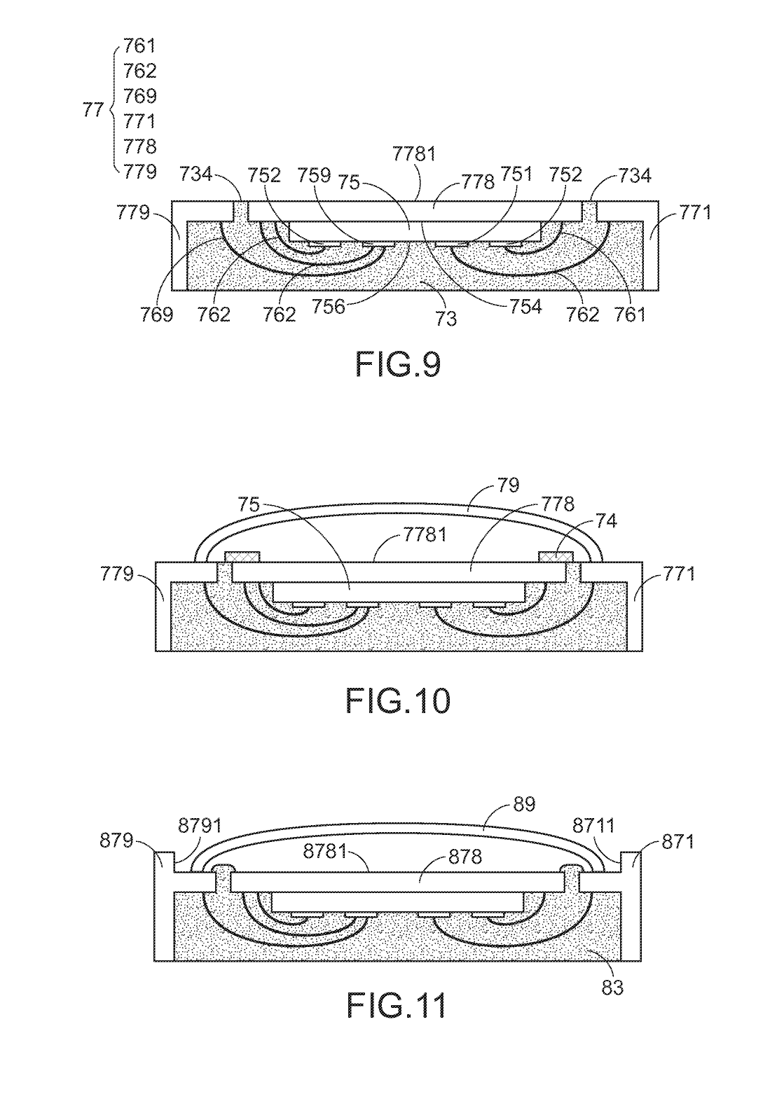

FIG. 9 is the fourth embodiment of this invention, which illustrates the side view of the Quad Flat package No-lead of the integrated-circuit of the present invention. FIG. 10 is the side view of the chip structure combined with the actuating member shown in FIG. 9. Referring to FIG. 9, the first surface 754 of the grain 75 is in contact with a grain holder 778 of a coupling member 77 (wire frame) in the fourth embodiment, and a plurality of pads 751, 752,759 are disposed on the second surface 756. The coupling member 77 further comprises a plurality of pins 771, 779 and a plurality of conductive structures 761, 762, 769. Wherein, the conductive structure 761 connects the pin 771 and pad 751, the conductive structure 762 connects the grain holder 778 and pad 752 or connects the pad 759, the conductive structure 769 connects the pin 779 and pad 759. The protective fixture 73, likes a sealing body, packages the grain 75, a plurality of pins 771, 779 and a plurality of conductive structures 761, 762, 769. The protective fixture 72 covers the grain holder 778 and exposes a surface 7781 of the grain holder 778. Therefore, the exposed surface 7781 and the surface 734 of the protective fixture 73 are one-piece bonding surface. Referring to FIG. 10, a bonding structure 74 is disposed on the surface 7781 and the surface 734 to be bonded by the actuating member 79. When the actuating member 79 does not receive a force, the actuating member 79 contacts the pin 771 and pin 779, and the bonding structure 74 could prevent the actuating member 79 from contacting the exposed surface 7781 of the grain holder 778. When the actuating member 79 receives an external force, the actuating member 79 could move a distance and contact the exposed surface 7781 of the grain holder 7781. The bonding structure 74, including but not limited, likes a cushion ring having an adequate shape, which uncovers parts of the surface 7781, for limiting the actuating member having a smooth contour, or the bonding structure 74 comprises a plurality of grooves formed in intervals, for being inserted by a protrusion of the actuating member.

As mentioned above, the grain holder 778 grounds, and the pad 752 electrically connected to the grain holder 778 is a grounding pad. When the actuating member 79 receives the external force, the actuating member 79 contacts the surface 7781, equal to contacts the grounding pad, and further actuating the grain 75 to process other signal.

FIG. 11 is the fifth embodiment of this invention, which illustrates the schematic side view of the chip structure comprising the similar Quad Flat Package. Compare to the fourth embodiment, pin 871 and pin 879 are respectively has a stage difference 8711, 8791 to be as limiting parts. The surface 8781 of the grain holder 878 and the stage difference 8711, 8791 are exposed through the protective fixture 83, 8711, 8791, and the protective fixture 83 is protruding exceed the surface 8781. Therefore, the surface 8781 of the grain holder 878 and the stage difference 8711, 8791 are one-piece bonding surface, for being combined with the actuating member 89. Thereby, when the external force is applied, the actuating member contacts the surface 8781.

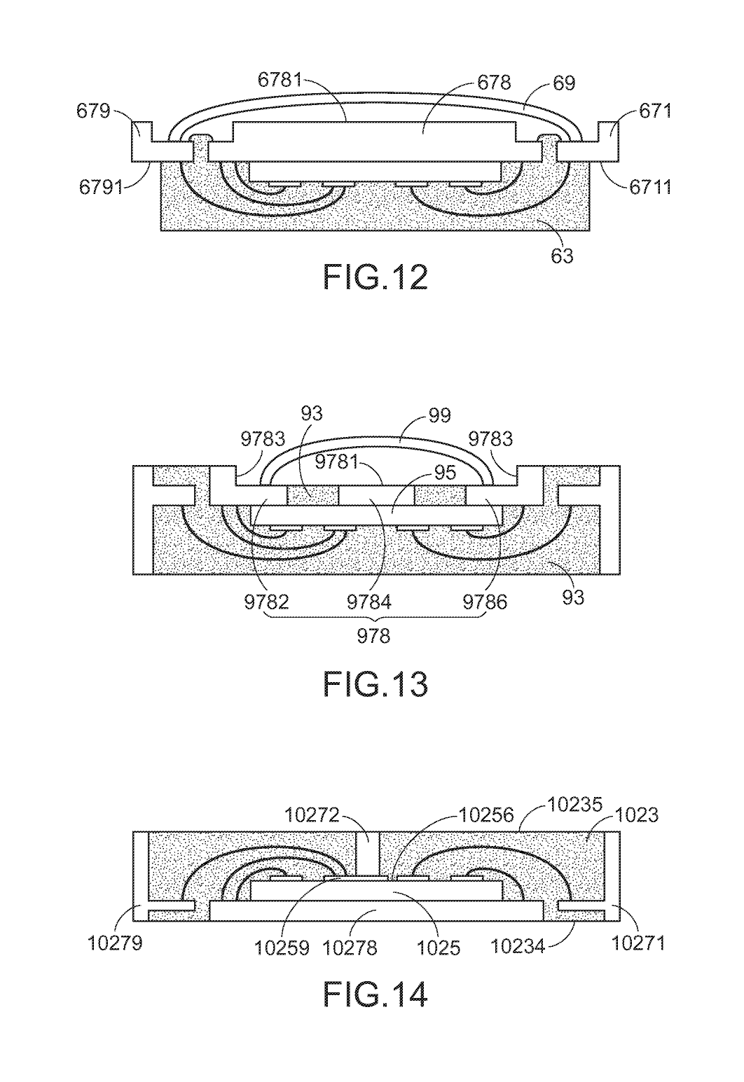

FIG. 12 is the sixth embodiment of this invention, which illustrates the chip structure comprising the Quad Flat Package. Compare to the fifth embodiment, the surface 6781 of the grain holder 678 and the pins 671, 678 having a stage difference are equal altitude and forming a one-piece bonding surface where the actuating member 69 is disposed. Further, the lateral wall of the protective fixture 63 is moved backward to expose the surface 6711 of the pin 671 and the surface 6791 of the pin 679. Wherein, the exposed surface 6711, 6791 could be electrically connected to a circuit board of the surroundings, but is not limited herein.

FIG. 13 is the seventh embodiment of this invention, which illustrates the chip structure comprising the Quad Flat Package No-lead. Compare to the fifth embodiment, the grain holder 978 has a stage difference 9783 to form a depressive surface 9781. Match the depressive surface 9781, the stage difference 9783 is served as a limiting structure. Further, the grain holder 978 comprises several parts 9782, 9784, 9786 divided by the protective fixture 93, each part 9782, 9784, 9786 is electrically connected to the grain 95, therefore, the grain holder 978 could provided a one-piece surface for actuating member 99 to combine the parts 9782, 9786 and to contact the part 9784 after a force is applied.

FIG. 14 is the eighth embodiment of this invention, which illustrates the structure comprising the Quad Flat Package No-lead. Compare to the fourth embodiment, the surface 10234 of the protective fixture 1023 is adjacent to the grain holder 10278. The surface 10235 of the protective fixture structure 1023 is opposite to an active surface 10256 of the grain 1025. Further, part of the signal pins 10271, 10279 provided by the wire frame connects the surface 10235 of the protective fixture 1023, and another part of the signal pins 10271, 10279 connects to the surface 10234 of the protective fixture 1023. Besides, the coupling member provides a conductive structure 10272 contacting the pad 10259 of the grain 1023, which penetrates through the protective fixture 1023 to the surface 10235 of the protective fixture 1023. Therefore, the surface 10235, the signal pin 10271, the signal pin 10279 and the conductive structure 10272 of the protective structure 1023 are jointly provided a one-piece bonding surface.

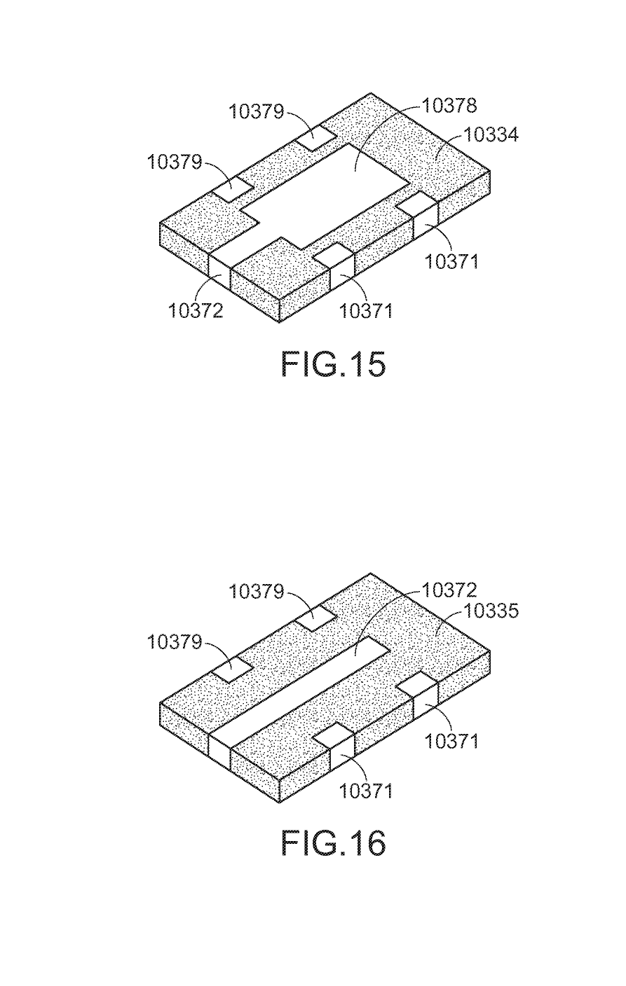

Selectively, the conductive structure could be served as an extending part of the grain holder, in other words, the conductive structure is made by the wire frame. Referring to FIGS. 15 and 16, which illustrates a schematic perspective view of the ninth embodiment at different aspect. Compare to the eighth embodiment, the conductive structure 10372 is extending from the grain holder 10378 Wherein, the grain holder 10378 and the signal pins 10371, 10379 are disposed on the surface 10334 of the protective fixture, and the conductive structure 10372 and the signal pin 10371, 10379 are disposed on another surface 10335 of the protective fixture. With this arrangement, the actuating member could be combined with the surface 10334 or the surface 10335 which is served as a one-piece bonding surface. Further, the lateral wall of the chip structure also could be served as the one-piece bonding surface, in the case of an external force is applied, the conductive structure could be contacted.

Selectively, the conductive structure could be one of the pins of the wire frame distributing arranged on one or more sides of the grain holder. Utilize a proper method, likes wire bonding, the grain holder and the pin is electrically connected with each other, and then the pin is extending to any surface or any lateral wall of the chip structure. The amount of the pins connecting to the grain holder is not limited herein. The pins connecting to the grain holder also could be arranged on different surface or lateral wall of the chip structure, so that there would be more options for the actuating member to contact thereto. Thus, the possibilities of setting the actuating member are enhanced.

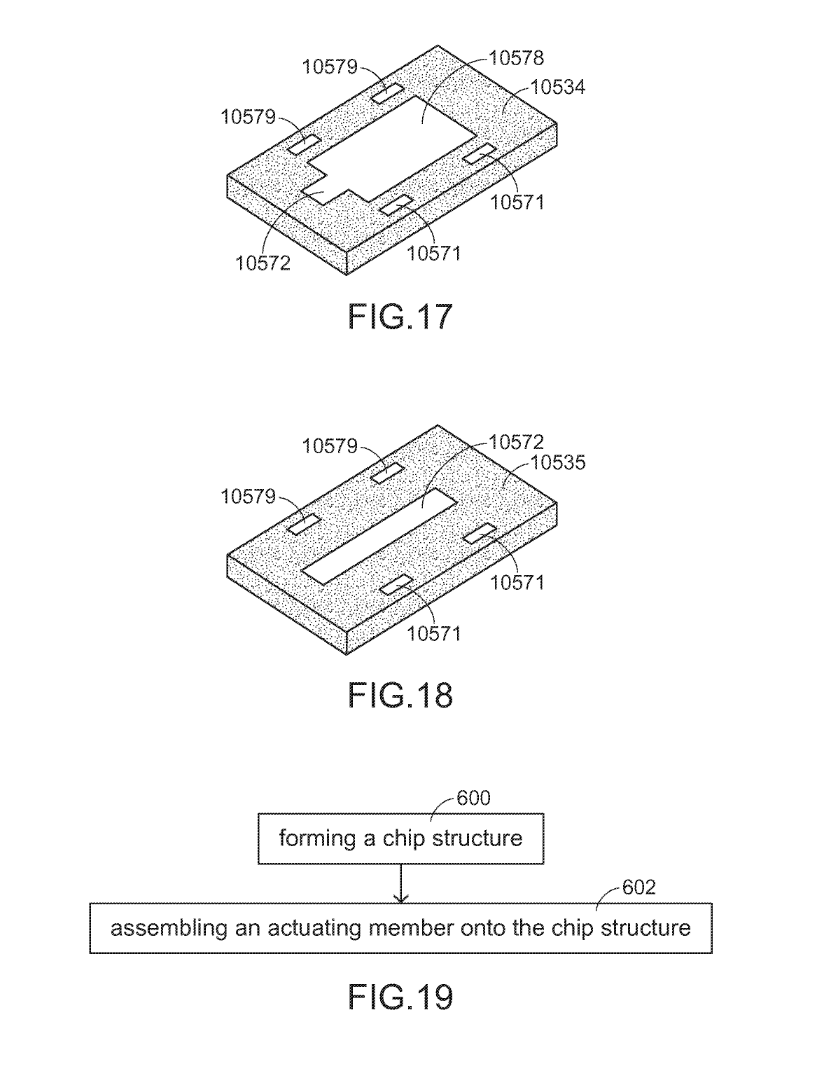

It should be noted herein that the deposition and the shape of the grain holder 10378, the conductive structure 10372, the signal pins 10371, 10379 are not limited in the ninth embodiment. As the tenth embodiment shown in FIG. 17 and FIG. 18, the grain holder 10578 merely exposed on the surface 10534 of the protective structure, the conductive structure 10572, signal pins 10571, 10579 are merely exposed on the surfaces 10534, 10535 of the protective structure, and the lateral walls of the chip structure are all protective fixture.

On the basis above, FIG. 19 illustrates a flow chart of a manufacturing method for a switch of this invention. The manufacturing method comprises step 600 and step 602. Step 600 is forming a chip structure, wherein the chip structure provides a one-piece bonding surface disposed. Step 602 is assembling an actuating member and the chip structure, wherein the actuating member is disposed on the one-piece bonding surface, and the actuating member has an operating area exposed outside the switch for receiving an external force. Further, the operating area is a force-exerting area of the integrated-circuit switch. The manufacturing method comprises a packaging method by packaging member, the packaging member comprises Single inline Package (SIP), dual-inline package, metal can package or flat package, wherein the flat package comprises Quad Flat Package (QFP), Quad Flat package No-lead (QFN), quad package with bump, quad package with guard ring, Pin Grid Array Package (PGA), Ball Grid Array Package (BGA), Chip Size Package (CSP), Chip On Board (COB), flip-chip, Leadless Chip Carrier, LCC or Quad flat non-leaded Package (QFN), Land Grid Array (LGA), Lead On Chip (LOC), Multi-Chip Module (MCM) or Over Molded Pad Array Carrier. Furthermore, the manufacturing method comprises a forming method that forming part of the actuating member integrally and assembling the other part of the actuating member to the chip structure.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. An integrated-circuit switch, comprising a chip structure having a one-piece bonding surface in contact with an actuating member, wherein the chip structure comprises:
a protective fixture;
a grain disposed in the protective fixture, wherein the grain is actuated as a result of contact with the actuating member; and
a coupling member disposed in the protective fixture and coupled with the grain, wherein the one-piece bonding surface is at least provided by the coupling member.

2. The integrated-circuit switch according to claim 1, wherein said coupling member comprises a wire frame with a plurality of signal pins, and the signal pins are electrically connected with a plurality of conductive pads of said grain correspondingly.

3. The integrated-circuit switch according to claim 2, wherein said coupling member further comprises a plurality of conductive structures for connecting said signal pins and said conductive pads; or said protective fixture comprises a plurality of attachment structures for fixing said signal pins onto an active face of said grain, and said conductive pads are disposed on the active face.

4. The integrated-circuit switch according to claim 2, wherein when said said actuating member contacts said chip structure, at least a part of any of said signal pins moves a distance to be electrically connected to and in contact with said conductive pads correspondingly; and the signal pin moving the distance provides the one-piece bonding surface.

5. The integrated-circuit switch according to claim 4, wherein said protective fixture comprises a plurality of sealing structures covering parts of said signal pins and said conductive pads; and the sealing structures further cover a plurality of conductive structures connecting said signal pins and said conductive pads.

6. The integrated-circuit switch according to claim 2, wherein at least a pair of said signal pins is disposed on said grain correspondingly; the pair of said signal pins provides said one-piece bonding surface; the pair of said signal pins further comprises a plurality of limiting parts; and said one-piece bonding surface further involves the limiting parts.

7. The integrated-circuit switch according to claim 2, wherein said coupling member further comprises a grain holder disposed on a back side of said grain, and said conductive pads are disposed on an active face opposite to the back side.

8. The integrated-circuit switch according to claim 7, wherein said grain holder is exposed outside said protective fixture so as to provide said one-piece bonding surface; or said grain holder comprises a plurality of separated parts, and the separated parts jointly form a groove away from said back side and provide said one-piece bonding surface, or said coupling member further comprises a plurality of conductive structures connecting parts of said signal pins to said grain holder.

9. The integrated-circuit switch according to claim 7, wherein said protective fixture comprises a sealing body sealing said grain and covering parts of said grain holder and said signal pins.

10. The integrated-circuit switch according to claim 9, wherein said one-piece bonding surface is additionally provided by said sealing body, said one-piece bonding surface involves the uncovered grain holder and said sealing body disposed around said grain holder; or said one-piece bonding surface is additionally provided by said sealing body, said one-piece bonding surface involves said uncovered grain holder, said sealant disposed around said grain holder and the uncovered signal pins.

11. The integrated-circuit switch according to claim 9, wherein parts of said signal pins are exposed outside said sealing body, the exposed parts of said signal pins are adjacent to an active face of said grain opposite to said sealing body, or adjacent to an active surface of said grain holder exposed via said sealing body, or parts of said signal pins are exposed on a lateral wall of said grain structure; wherein said one-piece bonding surface is additionally provided by said exposed parts of said signal pins.

12. The integrated-circuit switch according to claim 9, wherein the exposed grain holder further comprises an extending portion extending from said grain holder to a surface of said sealing body opposite to said active face of said grain, wherein the extending portion or the exposed grain holder is a part of said one-piece bonding surface.

13. The integrated-circuit switch according to claim 2, wherein some of said signal pins comprise an extending portion contacting a thermal conductive back side of said grain, and said conductive pads are disposed on an active surface opposite to the thermal conductive back side; wherein said one-piece bonding surface is provided by the extending portion.

14. The integrated-circuit switch according to claim 1, wherein said chip structure comprises a packaging member, the packaging member comprises a Single inline Package (SIP), a dual-inline package, a metal can package or a flat package, wherein the flat package comprises a Quad Flat Package (QFP), a Quad Flat package No-lead (QFN), a quad package with bump, a quad package with guard ring, a Pin Grid Array Package (PGA), a Ball Grid Array Package (BGA), a Chip Size Package (CSP), a Chip On Board (COB), a flip-chip, a Leadless Chip Carrier (LCC), a Quad flat non-leaded Package (QFN), a Land Grid Array (LGA), a Lead On Chip (LOC), a Multi-Chip Module (MCM), or an Over Molded Pad Array Carrier; wherein the packaging member is formed with said protective fixture and said coupling member.

15. The integrated-circuit switch according to claim 1, wherein said actuating member is in contact with said one-piece bonding surface and an external element in order, by turns or simultaneously.

16. The integrated-circuit switch according to claim 1, wherein said actuating member contacts said chip structure responding to an external force applied thereon; wherein said actuating member has an operating area exposed outside the integrated-circuit switch for receiving the external force; and the operating area is a force-exerting area of the integrated-circuit switch.

17. A manufacturing method for a switch, comprising the following steps of:
forming a chip structure having a one-piece bonding surface; and
assembling an actuating member and the chip structure;
wherein the actuating member is assembled to the one-piece bonding surface, and the actuating member has an operating area exposed outside the switch for receiving an external force.

18. The manufacturing method according to claim 17, wherein parts of the structure of the actuating member are integrally formed, and the other parts of the structure of the actuating member is assembled to the chip structure.

19. The manufacturing method according to claim 17, wherein the manufacturing method comprises a packaging method by a packaging member, the packaging member comprises a Single inline Package (SIP), a dual-inline package, a metal can package or a flat package, wherein the flat package comprises a Quad Flat Package (QFP), a Quad Flat package No-lead (QFN), a quad package with bump, a quad package with guard ring, a Pin Grid Array Package (PGA), a Ball Grid Array Package (BGA), a Chip Size Package (CSP), a Chip On Board (COB), a flip-chip, a Leadless Chip Carrier (LCC), a Quad flat non-leaded Package (QFN), a Land Grid Array (LGA), a Lead On Chip (LOC), a Multi-Chip Module (MCM) or an Over Molded Pad Array Carrier.

20. A switch, comprising:
a chip structure, comprising:
a protective fixture;
a grain disposed in the protective fixture; and
a coupling member disposed in the protective structure and electrically connected with the grain; and
an actuating member limited by the protective fixture and actuating the chip structure, wherein the actuating member is subjected to an external force to so as to contact both of the grain and the coupling member or contact either of the grain and the coupling member.

21. The switch according to claim 20, wherein said coupling member comprises a wire frame with a plurality of signal pins, and the signal pins are electrically connected with a plurality of conductive pads of said grain correspondingly; wherein when said actuating member contacts said chip structure, at least a portion of any of the signal pins moves a distance to be electrically connected to and in contact with the conductive pads correspondingly.

22. The switch according to claim 21, wherein said protective fixture comprises a plurality of sealing structures covering parts of said signal pins and said conductive pads; or the movable signal pins are said actuating member.

23. The switch according to claim 21, wherein the at least a pair of the signal pins is disposed on said grain correspondingly, and the pair of signal pins further comprises a plurality of limiting parts on which said actuating member is disposed.

24. The switch according to claim 21, wherein said coupling member further comprises a grain holder disposed on a back side of said grain, and said conductive pads are disposed on an active face opposite to the back side.

25. The switch according to claim 24, wherein said grain holder is exposed outside said protective fixture so as to provide said actuating member receiving said external force; or said grain holder comprises a plurality of separated parts, and the separated parts jointly form a groove away said back side and limiting said actuating member; or said coupling member further comprises a plurality of conductive structures for connecting parts of said signal pins to said grain holder; or said protective fixture comprises a sealing body sealing said grain and said signal pins and covering parts of said grain holder; or said signal pins have at least a stage difference to limit said actuating member.

26.-75. (canceled)
